(19) United States
(12) Patent Application Publication
(10) Pub. No.: US 2026/0231554 A1
(43) Pub. Date: Aug. 6, 2026

(54) INTEGRATED CHIP AND METHOD OF MANUFACTURING THE SAME

(71) Applicant: Taiwan Semiconductor Manufacturing Company, Ltd., Hsinchu (TW)

(72) Inventors: Kuan-Hua Lin, New Taipei City (TW); Min-Feng Kao, Chiayi City (TW); Yen-Ting Chiang, Tainan City (TW); Jen-Cheng Liu, Hsin-Chu City (TW)

(21) Appl. No.: 19/043,814

(22) Filed: Feb. 3, 2025

(51) Int. Cl. H10F 39/95; H01L 21/768; H01L 23/00; H01L 23/48; H01L 25/16; H10D 1/00; H10D 1/68; H10D 84/80

(52) U.S. Cl. CPC H10F 39/95; H10D 1/042; H10D 1/68; H10W 20/023; H10W 20/20; H10W 90/00; H10D 84/813; H10W 72/944; H10W 80/312; H10W 80/327; H10W 80/743; H10W 90/792

(57) ABSTRACT

An integrated chip includes a first transistor along a frontside of a first semiconductor substrate. A first conductive interconnect is on the frontside of the first semiconductor substrate and coupled to a source/drain of the first transistor. A backside through-substrate via (BTSV) extends through the first semiconductor substrate from a backside of the first semiconductor substrate through the frontside of the first semiconductor substrate to the first conductive interconnect. A capacitor is along the backside of the first semiconductor substrate and extends into the first semiconductor substrate from the backside of the first semiconductor substrate. The capacitor includes a first electrode layer, a second electrode layer, and an insulator layer between the first electrode layer and the second electrode layer. The first electrode layer is coupled to the source/drain of the first transistor by the BTSV and the first conductive interconnect.

### BACKGROUND

Complementary metal-oxide semiconductor (CMOS) image sensors are used in a wide range of modern-day electronic devices, such as, for example, cameras, tablets, smart phones, and so on. CMOS image sensors may be front-side illuminated (FSI) or back-side illuminated (BSI). Compared to FSI image sensors, BSI image sensors have better sensitivity, better angular response, and greater metal routing flexibility.

Many modern integrated chips include transistors as well as passive devices. Some examples of passive devices include capacitors, resistors, inductors, varactors, etc. Passive devices are widely used to control integrated chip characteristics, such as gains, time constants, etc. Some passive devices include integrated passive devices (IPDs). An IPD is a collection of one or more passive devices embedded into a single monolithic device and packaged as an integrated circuit (IC).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of an image sensor integrated chip including a photodetector in a first semiconductor substrate, a pixel transistor along a frontside of a second semiconductor substrate and coupled to the photodetector, and a lateral overflow integration capacitor (LOFIC) along a backside of the second semiconductor substrate and coupled to the pixel transistor by a backside through-substrate via (BTSV).

FIG. 2 illustrates a circuit diagram of some embodiments of the integrated chip of FIG. 1.

FIG. 3 illustrates a cross-sectional view of some embodiments of the LOFIC 170 of FIG. 1.

FIG. 4 illustrates a cross-sectional view of some embodiments of the integrated chip of FIG. 1 in which the BTSV is coupled to the LOFIC by a conductive bonding contact on the backside of the second semiconductor substrate.

FIG. 5 illustrates a top view of some embodiments of the integrated chip of FIG. 4.

FIGS. 6-7 illustrate cross-sectional views of some embodiments of the integrated chip of FIG. 1 in which the BTSV is coupled to the LOFIC by a backside conductive via.

FIG. 8 illustrates a cross-sectional view of some embodiments of the integrated chip of FIG. 1 in which the BTSV is directly coupled to the LOFIC.

FIGS. 9-31 illustrate cross-sectional views of some embodiments of a method for forming an image sensor integrated chip including a LOFIC along a backside of a semiconductor substrate and coupled to a pixel transistor that is along a frontside of the semiconductor substrate by a BTSV.

FIG. 32 illustrates a flow diagram of some embodiments of a method for forming an image sensor integrated chip including a LOFIC along a backside of a semiconductor substrate and coupled to a pixel transistor that is along a frontside of the semiconductor substrate by a BTSV.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An image sensor integrated chip includes a photodetector and a transfer transistor on a first semiconductor chip. The image sensor includes a pixel transistor and a lateral overflow integration capacitor (LOFIC) on a second chip bonded to the first semiconductor chip. The pixel transistor is arranged along a frontside of a semiconductor substrate of the second semiconductor chip. A first source/drain of the pixel transistor is selectively coupled to the photodetector by the transfer transistor. A second source/drain of the pixel transistor is coupled to the LOFIC.

In some integrated chips, the LOFIC is on the frontside of the semiconductor substrate. However, there may be limited space on the frontside of the semiconductor substrate. For example, conductive interconnects on the second semiconductor chip occupy much of the space on the frontside of the semiconductor substrate. Further, as pixel pitch decreases, the space on the frontside of the semiconductor substrate is further decreased. Consequently, the size of the LOFIC may be limited and thus the capacitance of the LOFIC may be limited. As a result, a performance of the image sensor may be limited.

In various embodiments of the present disclosure, the LOFIC is arranged on a backside of the semiconductor substrate where more space is available so that the size (and thus capacitance) of the LOFIC can be increased more easily. As a result, a performance of the image sensor may be improved. In various embodiments, the LOFIC is coupled to the second source/drain of the pixel transistor by a backside through-substrate via (BTSV) that extends through the semiconductor substrate from a backside of the semiconductor substrate through the frontside of the semiconductor substrate.

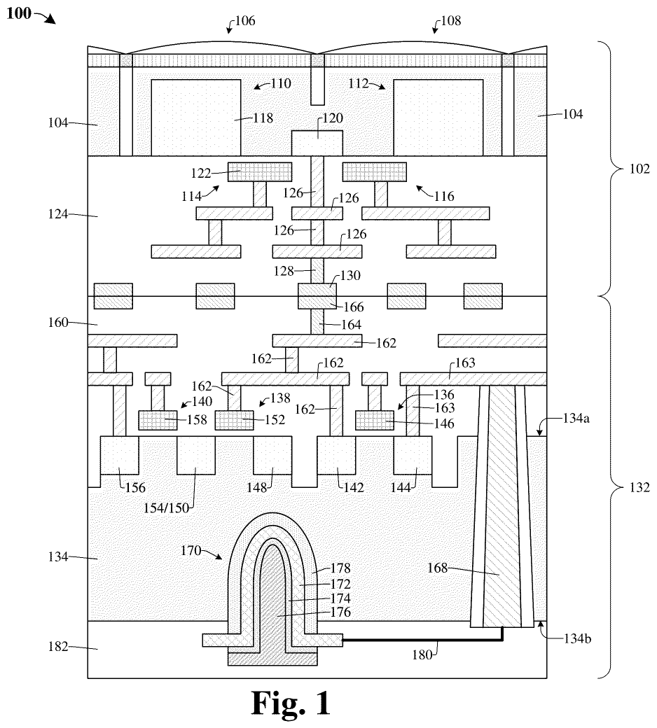

FIG. 1 illustrates a cross-sectional view 100 of some embodiments of an image sensor integrated chip including a photodetector 110 in a first semiconductor substrate 104, a pixel transistor 136 along a frontside 134a of a second semiconductor substrate 134 and coupled to the photodetector 110, and a lateral overflow integration capacitor (LOFIC) 170 along a backside 134b of the second semiconductor substrate 134 and coupled to the pixel transistor 136 by a backside through-substrate via (BTSV) 168.

The integrated chip includes a first semiconductor chip 102. The first semiconductor chip 102 includes a first semiconductor substrate 104. A first pixel 106 and a second pixel 108 are arranged along the first semiconductor substrate 104. The first pixel 106 includes a first photodetector 110 in the first semiconductor substrate 104 and a first transfer transistor 114 along the first semiconductor substrate 104. The second pixel 108 includes a second photodetector 112 in the first semiconductor substrate 104 and a second transfer transistor 116 along the first semiconductor substrate 104. The first transfer transistor 114 includes a first source/drain 118, a second source/drain 120, and a gate 122. In some embodiments, the first photodetector 110 is a photodiode formed by the first source/drain 118 and the first semiconductor substrate 104.

A first dielectric structure 124 comprising a plurality of dielectric layers is on the first semiconductor chip 102. Conductive interconnects 126 (e.g., conductive contacts, conductive vias, conductive lines, etc.) are on the first semiconductor chip 102 and within the first dielectric structure 124. A first conductive bonding contact 128 and a first conductive bonding pad 130 are on the first semiconductor chip 102 and within the first dielectric structure 124.

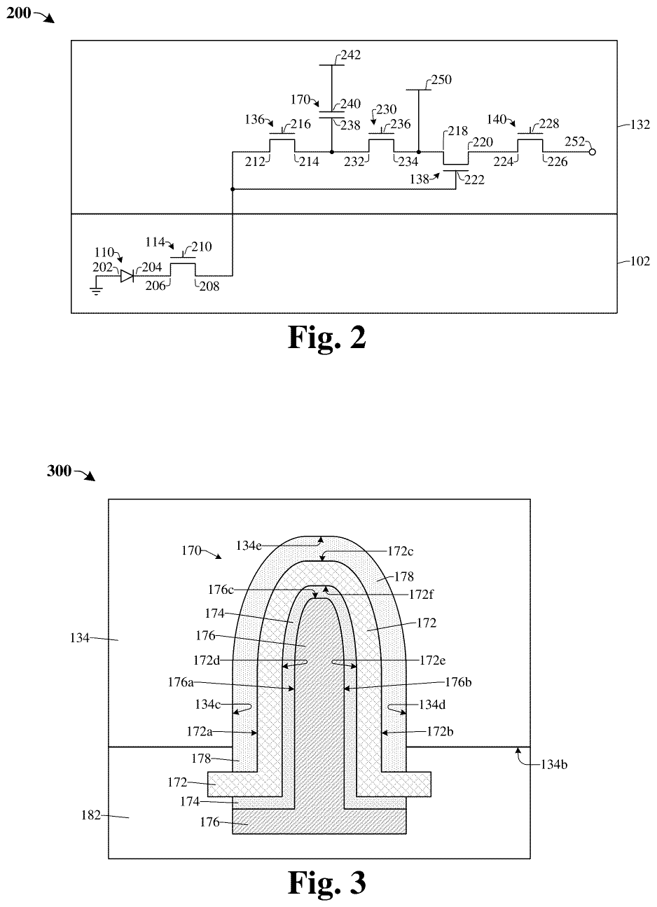

The integrated chip includes a second semiconductor chip 132 bonded to the first semiconductor chip 102. The second semiconductor chip 132 includes a second semiconductor substrate 134. A first pixel transistor 136, a second pixel transistor 138, a third pixel transistor 140, and a fourth pixel transistor (e.g., 230 of FIG. 2) are arranged along a frontside 134a of the second semiconductor substrate 134. The first pixel transistor 136 includes a first source/drain 142, a second source/drain 144, and a gate 146. The second pixel transistor 138 includes a first source/drain 148, a second source/drain 150, and a gate 152. The third pixel transistor 140 includes a first source/drain 154, a second source/drain 156, and a gate 158. In some embodiments, source/drain 154 and source/drain 150 are one and the same. Source/drain(s) may refer to a source or a drain, individually or collectively dependent upon the context.

A second dielectric structure 160 comprising a plurality of dielectric layers is on the second semiconductor chip 132. Conductive interconnects 162, 163 (e.g., conductive contacts, conductive vias, conductive lines, etc.) are on the second semiconductor chip 132 and within the second dielectric structure 160. A second conductive bonding contact 164 and a second conductive bonding pad 166 are on the second semiconductor chip 132 and within the second dielectric structure 160. The second conductive bonding pad 166 is bonded and coupled to the first conductive bonding pad 130 at an interface where the second semiconductor chip 132 and the first semiconductor chip 102 are bonded together. Further, the second dielectric structure 160 is bonded to the first dielectric structure 124 at the interface. Source/drain 142 of transistor 136 and gate 152 of transistor 138 are coupled to source/drain 120 of transistors 114, 116 by conductive interconnects 162, the second conductive bonding contact 164, the second conductive bonding pad 166, the first conductive bonding pad 130, the first conductive bonding contact 128, and conductive interconnects 126.

A backside through-substrate via (BTSV) 168 is on the second semiconductor chip 132. The BTSV 168 extends through the second semiconductor substrate 134 from a backside 134b of the second semiconductor substrate through the frontside 134a of the second semiconductor substrate 134. The BTSV 168 extends into the second dielectric structure 160 to a conductive line on the second semiconductor chip 132. The BTSV 168 is coupled to the second source/drain 144 of the first pixel transistor 136 by conductive interconnects 163 (e.g., a contact and the conductive line).

A backside dielectric structure 182 and a lateral overflow integration capacitor (LOFIC) 170 are on the second semiconductor chip 132. The backside dielectric structure 182 and the LOFIC 170 are arranged along the backside 134b of the second semiconductor substrate 134. The LOFIC 170 extends into the second semiconductor substrate 134 from the backside 134b of the second semiconductor substrate 134. The LOFIC includes a first electrode layer 172, a second electrode layer 176, and an insulator layer 174 between the first electrode layer 172 and the second electrode layer 176. A dielectric layer 178 is between (e.g., separates) the first electrode layer 172 and the second semiconductor substrate 134. The first electrode layer 172 is coupled to the BTSV 168 on the backside 134b of the second semiconductor substrate 134, as illustrated by line 180 which symbolizes the electrical connection between the first electrode layer 172 and the BTSV 168. Thus, the first electrode layer 172 of the LOFIC 170 is coupled to the second source/drain 144 of the first pixel transistor 136 by the BTSV 168 and conductive interconnects 163. Further, the first pixel transistor 136 and the first transfer transistor 114 selectively couple the first electrode layer 172 of the LOFIC 170 to the first photodetector 110. The second electrode layer 176 is coupled to a reference voltage terminal (e.g., 242 of FIG. 2).

By arranging the LOFIC 170 along the backside 134b of the second semiconductor substrate 134, the capacitance of the LOFIC 170 can be increased and thus the performance of the image sensor can be improved. For example, there may be more space available on the backside 134b than on the frontside 134a. Thus, the size of the LOFIC 170 (and hence the capacitance of the LOFIC 170) can be more easily increased when the LOFIC 170 is disposed along the backside 134b.

FIG. 2 illustrates a circuit diagram 200 of some embodiments of the integrated chip of FIG. 1.

In some embodiments, the photodetector 110 is a photodiode having a first terminal 202 (e.g., corresponding to the first semiconductor substrate 104) and a second terminal 204 (e.g., corresponding to source/drain 118).

The first transfer transistor 114 has a first terminal 206 (e.g., corresponding to source/drain 118), a second terminal 208 (e.g., corresponding to source/drain 120), and a control terminal 210 (e.g., corresponding to gate 122). Terminal 206 is coupled to terminal 204.

The first pixel transistor 136 has a first terminal 212 (e.g., corresponding to source/drain 142), a second terminal 214 (e.g., corresponding to source/drain 144), and a control terminal 216 (e.g., corresponding to gate 146). Terminal 212 is coupled to terminal 208.

The second pixel transistor 138 (e.g., a source follower transistor) has a first terminal 218 (e.g., corresponding to source/drain 148), a second terminal 220 (e.g., corresponding to source/drain 150), and a control terminal 222 (e.g., corresponding to gate 152). Control terminal 222 is coupled to terminal 208 and terminal 212. Terminal 218 is coupled to a supply voltage terminal 250 (e.g., a VDD terminal).

The third pixel transistor 140 (e.g., a row select transistor) has a first terminal 224 (e.g., corresponding to source/drain 154), a second terminal 226 (e.g., corresponding to source/drain 156), and a control terminal 228 (e.g., corresponding to gate 158). Terminal 224 is coupled to terminal 220. Terminal 226 is coupled to an output terminal 252.

The fourth pixel transistor 230 (e.g., a reset transistor) has a first terminal 232 (e.g., corresponding to a first source/drain), a second terminal 234 (e.g., corresponding to a second source/drain), and a control terminal 236 (e.g., corresponding to a gate). Terminal 232 is coupled to terminal 214. Terminal 234 is coupled to the supply voltage terminal 250.

The LOFIC 170 has a first terminal 238 (e.g., corresponding to the first electrode layer 172) and a second terminal 240 (e.g., corresponding to the second electrode layer 176). Terminal 238 is coupled to terminal 214 and terminal 232. Terminal 240 is coupled to a reference voltage terminal 242 (e.g., a ground terminal).

FIG. 3 illustrates a cross-sectional view 300 of some embodiments of the LOFIC 170 of FIG. 1.

The first electrode layer 172 has a lateral portion that is spaced below the backside 134b of semiconductor substrate 134 and a vertical portion that extends from below the backside 134b to between a first sidewall 134c and a second sidewall 134d of semiconductor substrate 134. Outer sidewalls 172a, 172b of the first electrode layer 172 are spaced from sidewalls 134c, 134d of semiconductor substrate 134 with dielectric layer 178 therebetween. Further, an upper surface 172c of the first electrode layer 172 is spaced from a lower surface 134e of semiconductor substrate 134 with dielectric layer 178 therebetween. Dielectric layer 178 extends below the backside 134b of semiconductor substrate 134.

The second electrode layer 176 has a lateral portion that is spaced below the lateral portion of the first electrode layer 172 and a vertical portion that extends from below the backside 134b to between sidewalls 134c, 134d of semiconductor substrate 134. Sidewalls 176a, 176b of the second electrode layer 176 are spaced from inner sidewalls 172d, 172e of the first electrode layer 172 with insulator layer 174 therebetween. Further, an upper surface 176c of the second electrode layer 176 is spaced from a lower surface 172f of the first electrode layer 172 with insulator layer 174 therebetween.

In some embodiments, the LOFIC 170 could have additional electrode layers and additional insulator layers. For example, in some embodiments, the LOFIC 170 has a third electrode layer (not shown) between the first electrode layer 172 and the insulator layer 174, and a second insulator layer (not shown) between the third electrode layer and the first electrode layer 172. In some such embodiments, the first electrode layer and the second electrode layer 176 are coupled together to form a first electrode, and the third electrode layer forms a second electrode separate from the first electrode.

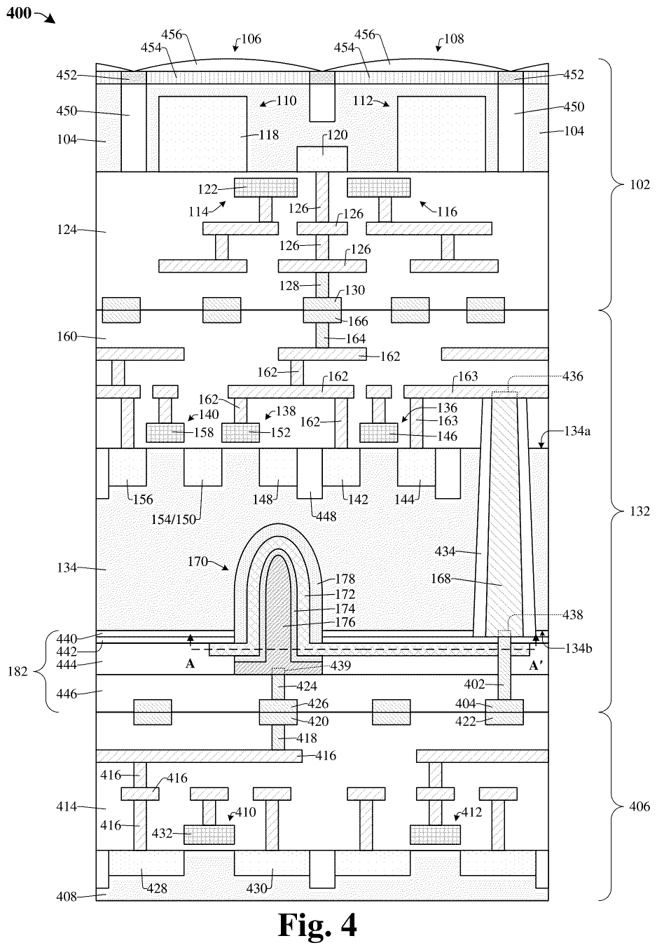

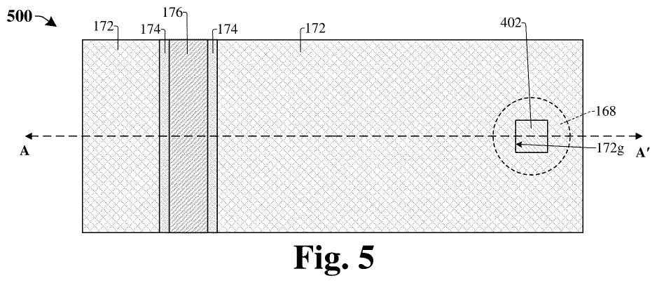

FIG. 4 illustrates a cross-sectional view 400 of some embodiments of the integrated chip of FIG. 1 in which the BTSV 168 is coupled to the first electrode layer 172 of the LOFIC 170 by a backside conductive bonding contact 402 on the backside 134b of the second semiconductor substrate 134. FIG. 5 illustrates a top view 500 of some embodiments of the integrated chip of FIG. 4. In some embodiments, top view 500 of FIG. 5 may, for example, be taken across line A-A′ of FIG. 4.

Referring to FIG. 4 and FIG. 5, the first electrode layer 172 extends directly under the BTSV 168, and backside conductive bonding contact 402 extends from a backside conductive bonding pad 404 through the first electrode layer 172 to the BTSV 168. Backside conductive bonding contact 402 directly contacts sidewalls 172g of the first electrode layer 172 and a lower surface of the BTSV 168, thus coupling the BTSV 168 to the first electrode layer 172. The first electrode layer 172 laterally surrounds backside conductive bonding contact 402. In some embodiments, an upper surface of backside conductive bonding contact 402 is on the lower surface of the BTSV 168. In some other embodiments, backside conductive bonding contact 402 extends slightly into the BTSV 168 (e.g., as illustrated by dashed line 438).

A backside conductive bonding contact 424 extends from a backside conductive bonding pad 426 to the second electrode layer 176 and directly contacts the second electrode layer 176. In some embodiments, an upper surface of backside conductive bonding contact 424 is on a lower surface of the second electrode layer 176. In some other embodiments, backside conductive bonding contact 424 extends slightly into the second electrode layer 176 (e.g., as illustrated by dashed line 439).

In some cases, by coupling the first electrode layer 172 to the BTSV 168 with backside conductive bonding contact 402, and by directly coupling backside conductive bonding contact 424 to the second electrode layer 176, a cost and/or process time of the integrated chip can be reduced.

The BTSV 168 has a lower surface below the backside 134b of semiconductor substrate 134 and an upper surface above the frontside 134a of semiconductor substrate 134. A dielectric layer 434 is between the BTSV 168 and semiconductor substrate 134. Dielectric layer 434 lines sidewalls of the BTSV 168 from the lower surface of the BTSV 168 to the upper surface of the BTSV 168. In some embodiments, a width of the BTSV decreases from the lower surface to the upper surface. In some embodiments, the upper surface of the BTSV 168 is on a bottom surface of the overlying conductive line 163. In some other embodiments, the BTSV 168 extends slightly into the overlying conductive line 163 (e.g., as illustrated by dashed line 436).

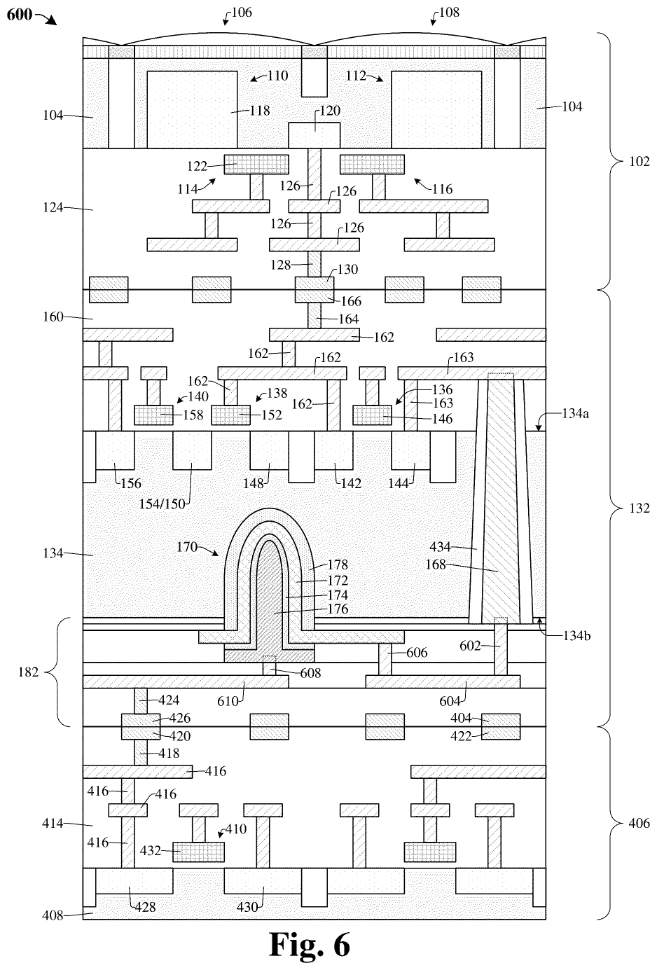

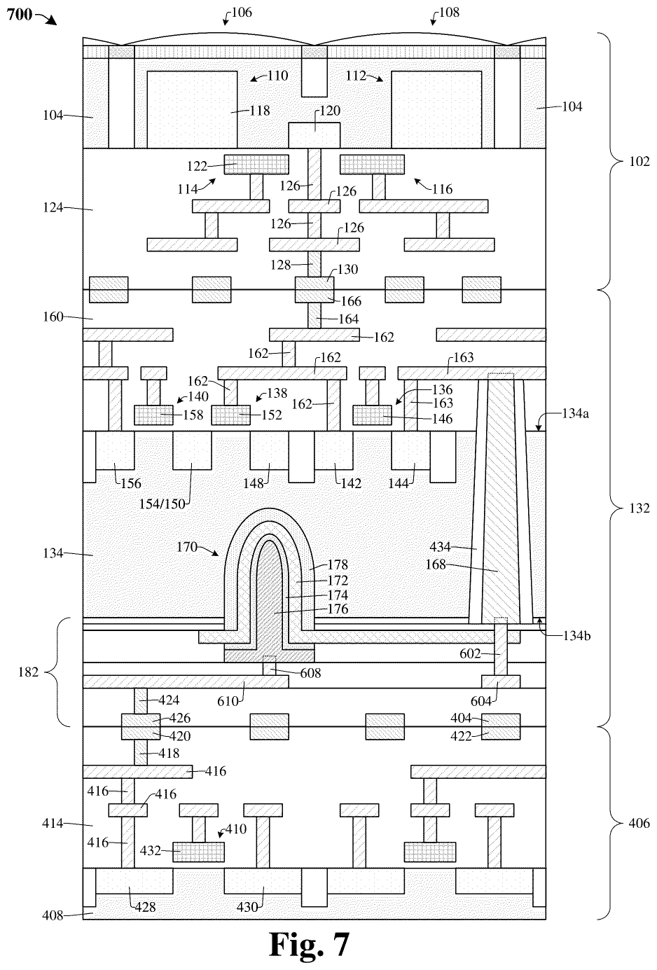

FIGS. 6-7 illustrate cross-sectional views 600-700 of some embodiments of the integrated chip of FIG. 1 in which the BTSV 168 is coupled to the first electrode layer 172 of the LOFIC 170 by a backside conductive via 602.

In some embodiments (e.g., as illustrated in FIG. 6), backside conductive via 602 extends from a backside conductive line 604 to the BTSV 168, and a backside conductive via 606 extends from backside conductive line 604 to the first electrode layer 172, thus coupling the BTSV 168 to the first electrode layer 172.

In some embodiments (e.g., as illustrated in FIG. 7), backside conductive via 602 extends from backside conductive line 604 through the first electrode layer 172 to the BTSV 168 and directly contacts the first electrode layer 172 and the BTSV 168, thus coupling the BTSV 168 to the first electrode layer 172.

In some cases, by coupling the first electrode layer 172 to the BTSV 168 with backside conductive interconnects 602, 604, 606, and by coupling the second electrode layer 176 to backside conductive bonding contact 424 by backside conductive interconnects 608, 610, a design flexibility of the integrated chip can be improved.

Referring to FIG. 6 and FIG. 7, a backside conductive via 608 extends from a backside conductive line 610 to the second electrode layer 176, and backside conductive bonding contact 424 extends from backside conductive bonding pad 426 to backside conductive line 610.

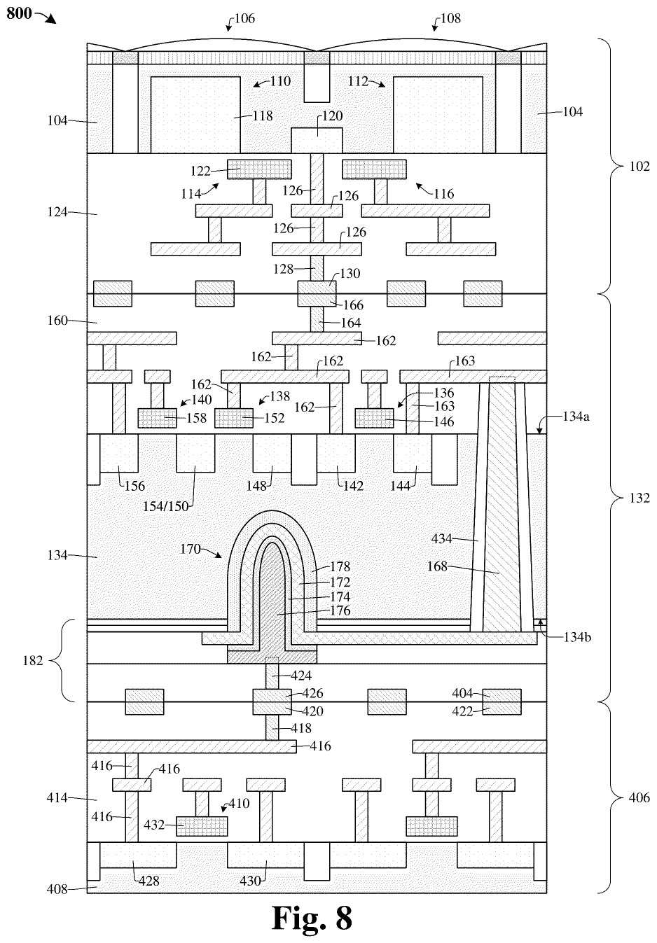

FIG. 8 illustrates a cross-sectional view 800 of some embodiments of the integrated chip of FIG. 1 in which the BTSV 168 is directly coupled to the first electrode layer 172 of the LOFIC 170.

The first electrode layer 172 extends directly under the BTSV 168 and directly contacts the lower surface of the BTSV 168. In some embodiments, the first electrode layer covers the lower surface of the BTSV 168. In some cases, by directly coupling the first electrode layer 172 to the BTSV 168, a cost and/or process time of the integrated chip can be reduced.

Referring to FIGS. 4-8, in some embodiments, a reference transistor 410 selectively couples the second electrode layer 176 to the reference voltage terminal (e.g., 242 of FIG. 2). In some embodiments, the reference transistor 410 is on a third semiconductor chip 406 that is bonded to the second semiconductor chip 132. The third semiconductor chip 406 includes a third semiconductor substrate 408. Transistors 410, 412 are arranged along the third semiconductor substrate 408. A third dielectric structure 414, conductive interconnects 416, a conductive bonding contact 418, and conductive bonding pads 420, 422 are on the third semiconductor chip 406. Conductive bonding pad 420 is bonded and coupled to backside conductive bonding pad 426 at an interface where the second semiconductor chip 132 and the third semiconductor chip 406 are bonded together. Conductive bonding pad 422 is bonded and coupled to backside conductive bonding pad 404 at the interface. A first source/drain 428 of the reference transistor 410 is coupled to the second electrode layer 176 by conductive bonding contacts 424, 418, conductive bonding pads 426, 420, and conductive interconnects 416. A second source/drain 430 of the reference transistor 410 is coupled to the reference voltage terminal (e.g., 242 of FIG. 2).

In some embodiments, backside dielectric structure 182 comprises a plurality of dielectric layers 440, 442, 444, 446. In some embodiments, shallow trench isolation (STI) structure(s) 448 is/are between pixel transistors on the second semiconductor chip 132. In some embodiments, deep trench isolation (DTI) structure(s) 450 is/are between pixels on the first semiconductor chip 102. In some embodiments, an anti-reflection layer (not shown) is on the backside of the first semiconductor substrate 104. In some embodiments, a passivation layer (not shown) is on the anti-reflection layer. In some embodiments, a grid structure 452 is over the DTI structure(s) 450 and on the passivation layer. In some embodiments, color filters 454 are over the passivation layer. In some embodiments, micro-lenses 456 are over the color filters 454.

In some embodiments, semiconductor substrates 104, 134, 408 comprise silicon or some other suitable material(s). In some embodiments, transistors 114, 116, 136, 138, 140, 410, 412 are metal-oxide-semiconductor field-effect transistors (MOSFETs), junction FETs, fin FETs, gate all-around (GAA) FETs, or some other suitable type of transistors. In some embodiments, source/drains 118, 120, 142, 144, 148, 150, 154, 156, 428, 430 are doped regions of semiconductor substrate. In some embodiments, gates 122, 146, 152, 158, 432 comprise polysilicon, tungsten, tungsten nitride, titanium nitride, tantalum nitride, or some other suitable gate electrode material(s). In some embodiments, the dielectric layers of dielectric structures 124, 160, 182, 414 comprise silicon oxide, silicon nitride, silicon carbide, silicon oxynitride, silicon oxycarbide, hafnium oxide, or some other suitable material(s). In some embodiments, conductive interconnects 126, 162, 163, 416, 602, 604, 608, 610 comprise copper, tungsten, aluminum, gold, silver, or some other suitable material(s). In some embodiments, conductive bonding pads 130, 166, 404, 426, 420, 422 and conductive bonding contacts 128, 164, 402, 424, 418 comprise copper or some other suitable material. In some embodiments, the BTSV 168 comprises copper, tungsten, or some other suitable material(s). In some embodiments, dielectric layer 434 comprises silicon oxide, silicon nitride, or some other suitable material(s). In some embodiments, dielectric layer 178 silicon oxide, silicon nitride, or some other suitable material(s). In some embodiments, electrode layers 172, 176 comprise titanium nitride, tantalum nitride, or some other suitable material(s). In some embodiments, insulator layer 174 comprises a high-k dielectric (e.g., aluminum oxide, hafnium oxide, zirconium oxide, or the like) or some other suitable material.

FIGS. 9-31 illustrate cross-sectional views 900-3100 of some embodiments of a method for forming an image sensor integrated chip including a LOFIC 170 along a backside 134b of a semiconductor substrate 134 and coupled to a pixel transistor 136 that is along a frontside 134a of the semiconductor substrate 134 by a BTSV 168 that extends through the semiconductor substrate 134. Although FIGS. 9-31 are described in relation to a method, it will be appreciated that the structures disclosed in FIGS. 9-31 are not limited to such a method, but instead may stand alone as structures independent of the method.

As shown in cross-sectional view 900 of FIG. 9, pixels 106, 108 are formed on a first semiconductor chip 102. For example, photodetectors 110, 112 are formed in a first semiconductor substrate 104 and transfer transistors 114, 116 are formed along the first semiconductor substrate 104. Further, a dielectric structure 124, conductive interconnects 126, conductive bonding contact 128, and conductive bonding pad 130 are formed on a frontside of the first semiconductor substrate 104. Deep trench isolation (DTI) structure(s) 450 is/are formed extending into the first semiconductor substrate 104 from a backside of the first semiconductor substrate 104.

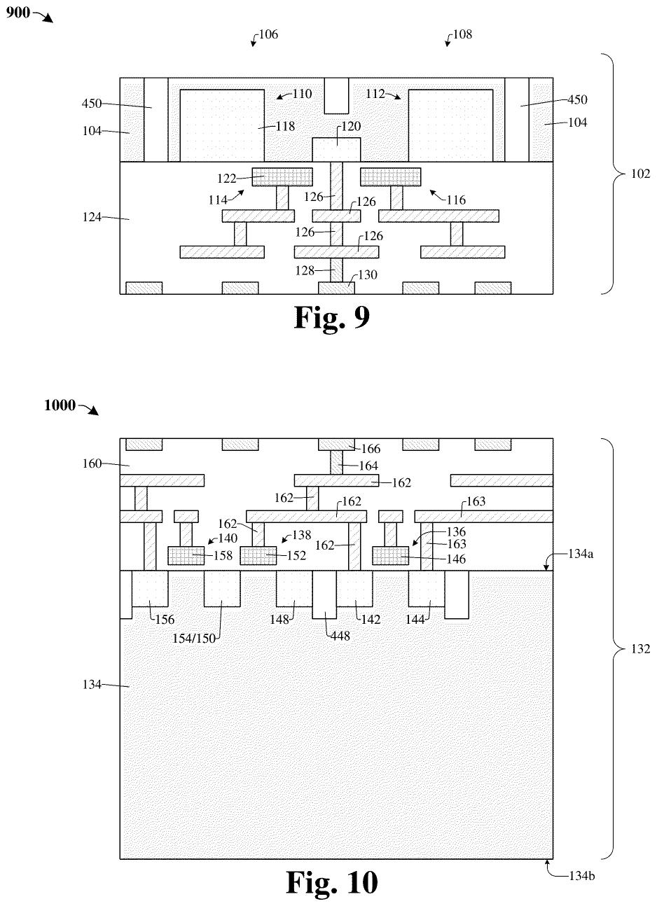

As shown in cross-sectional view 1000 of FIG. 10, pixel transistors 136, 138, 140 are formed along a frontside 134a of a second semiconductor substrate 134 of a second semiconductor chip 132. Further, a dielectric structure 160, conductive interconnects 162, 163, conductive bonding contact 164, and conductive bonding pad 166 are formed on the frontside 134a of the second semiconductor substrate 134.

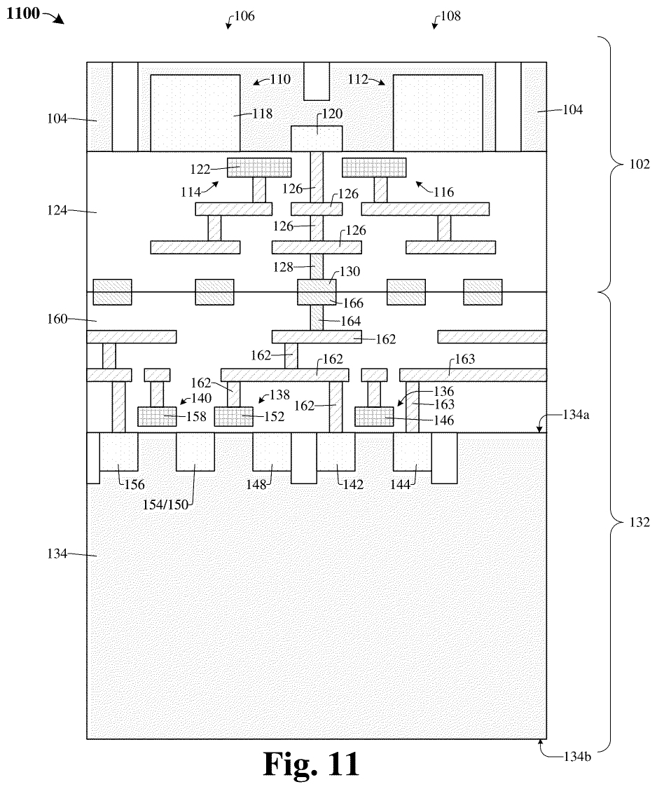

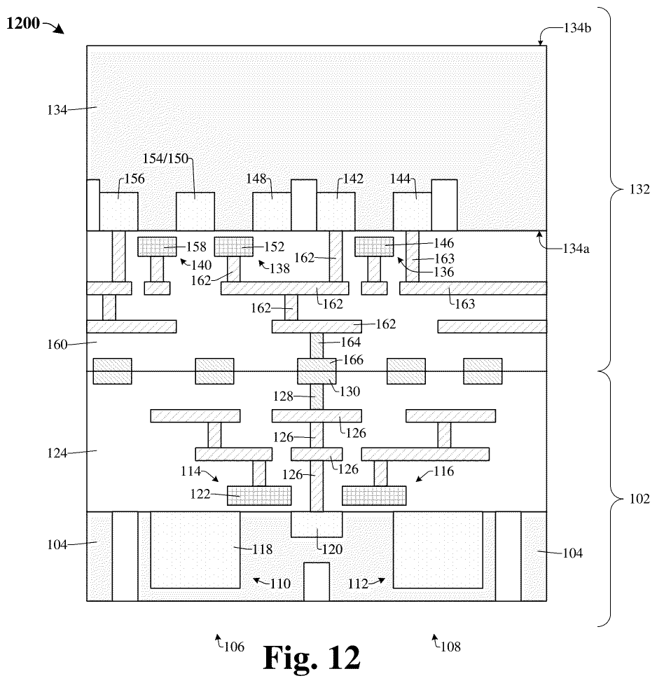

As shown in cross-sectional view 1100 of FIG. 11, the second semiconductor chip 132 and the first semiconductor chip 102 are bonded together. For example, conductive bonding pad 166 and conductive bonding pad 130 are bonded together at an interface between the second semiconductor chip 132 and the first semiconductor chip 102. Further, dielectric structure 160 and dielectric structure 124 are bonded together at the interface. In some embodiments, the bonding comprises a fusion bonding process, a direct bonding process, or some other suitable process.

As shown in cross-sectional view 1200 of FIG. 12, the second semiconductor substrate 134 is thinned from a backside 134b of the second semiconductor substrate 134. In some embodiments, the thinning comprises an etching process, a chemical mechanical planarization (CMP) process, or some other suitable process.

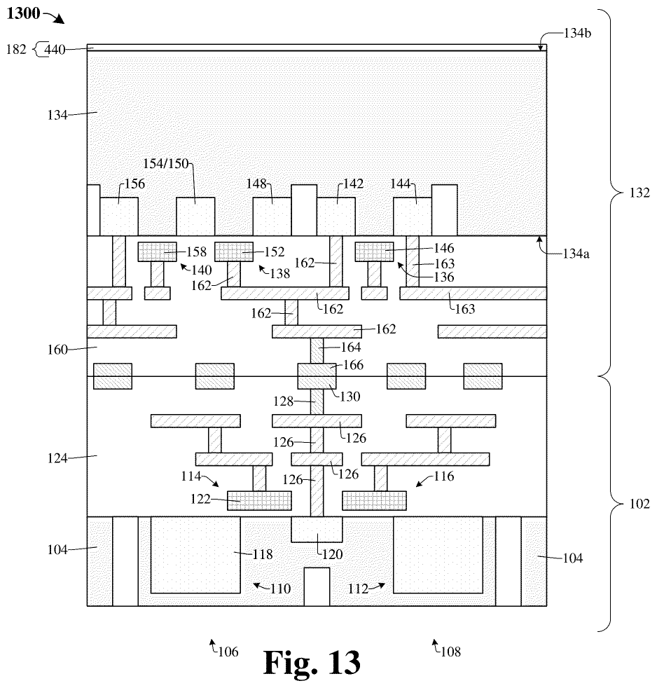

As shown in cross-sectional view 1300 of FIG. 13, a dielectric layer 440 is deposited on the backside 134b of the second semiconductor substrate 134. In some embodiments, dielectric layer 440 comprises silicon oxide, silicon nitride, or some other suitable material and is deposited by a chemical vapor deposition (CVD) process, a physical vapor deposition (PVD) process, an atomic layer deposition (ALD) process, or some other suitable process.

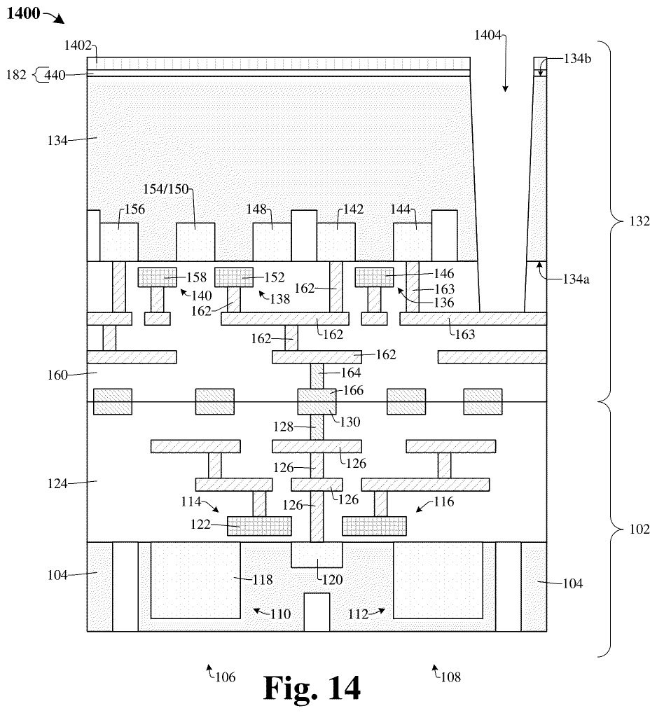

As shown in cross-sectional view 1400 of FIG. 14, dielectric layer 440, semiconductor substrate 134, and dielectric structure 160 are etched to form a backside through-substrate via opening 1404 therein. The etching extends from the backside 134b of semiconductor substrate 134 through the frontside 134 a to conductive line 163. In some embodiments, the backside through-substrate via opening 1404 is delimited by sidewalls of dielectric layer 440, sidewalls of semiconductor substrate 134, sidewalls of dielectric structure 160, and a lower surface of conductive line 163. In some embodiments, a masking layer 1402 is formed over dielectric layer 440 and the etching is performed according to the masking layer 1402. In some embodiments, the masking layer comprises a photoresist material, a hard mask material, or some other suitable material. In some embodiments, the etching comprises a dry etching process such as, for example, a plasma etching process, a reactive ion etching process, an ion beam etching process, or some other suitable process.

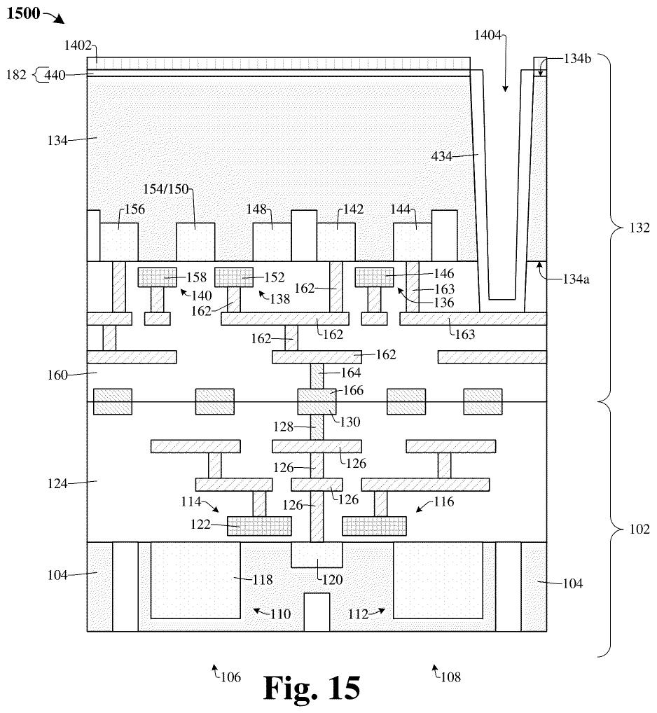

As shown in cross-sectional view 1500 of FIG. 15, a dielectric layer 434 is deposited in the backside through-substrate via opening 1404 (e.g., on sidewalls of dielectric layer 440, sidewalls of semiconductor substrate 134, sidewalls of dielectric structure 160, and the lower surface of conductive line 163). Dielectric layer 434 lines the backside through-substrate via opening 1404 and fills portion of the backside through-substrate via opening 1404. In some embodiments, dielectric layer 434 comprises silicon oxide, silicon nitride, or some other suitable material and is deposited by a CVD process, a PVD process, an ALD process, or some other suitable process. In some embodiments, dielectric layer 434 is deposited with masking layer 1402 in place over dielectric layer 440.

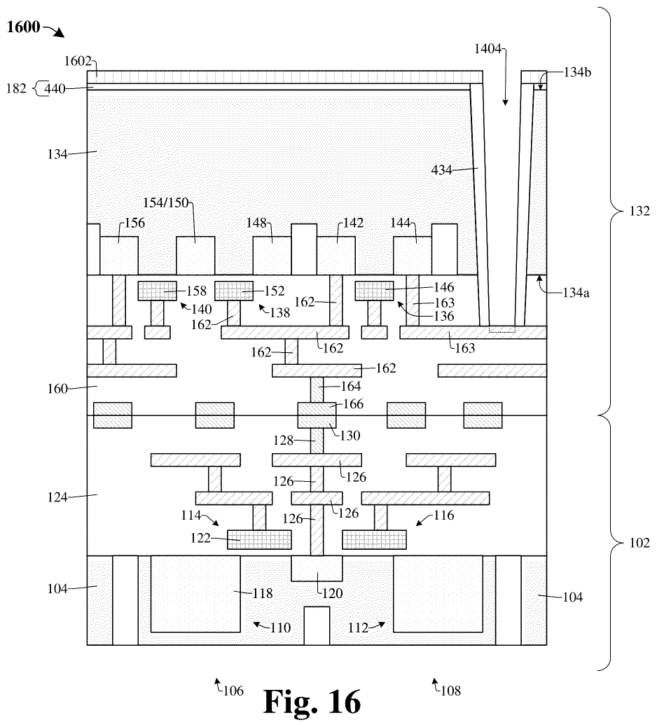

As shown in cross-sectional view 1600 of FIG. 16, dielectric layer 434 is etched to uncover the lower surface of conductive line 163 at the bottom of the backside through-substrate via opening 1404. The etching removes a portion of dielectric layer 434 from the lower surface of conductive line 163. In some embodiments, the etching extends slightly into conductive line 163. In some embodiments, a masking layer 1602 is formed over dielectric layers 440, 434 and the etching is performed according to the masking layer 1602. In some embodiments, the etching comprises a dry etching process or some other suitable process.

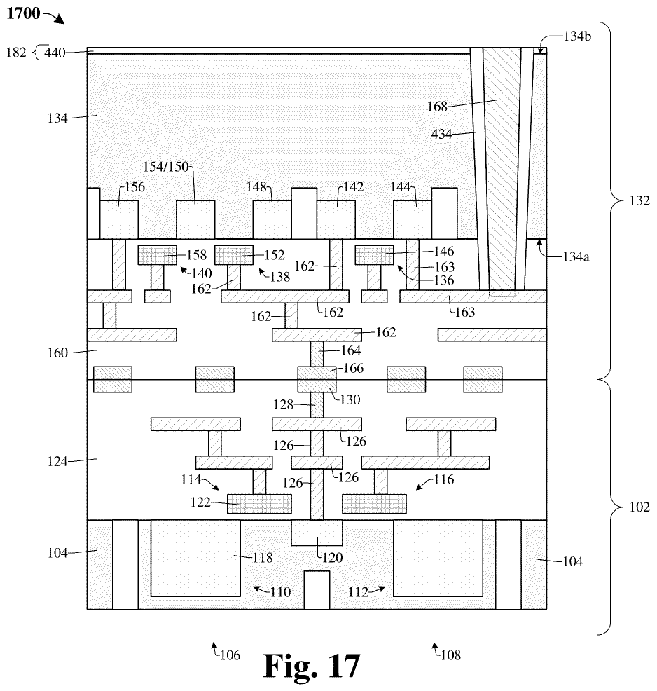

As shown in cross-sectional view 1700 of FIG. 17, a backside through-substrate via (BTSV) 168 is formed in the backside through-substrate via opening 1404 (e.g., between sidewalls of dielectric layer 434) and on the lower surface of conductive line 163. In some embodiments, forming the BTSV comprises depositing a conductive barrier layer in the backside through-substrate via opening 1404 and depositing a conductive fill layer over the conductive barrier layer to fill the backside through-substrate via opening 1404. In some embodiments, the BTSV 168 comprises copper, tungsten, aluminum, or some other suitable material and is deposited by a CVD process, a PVD process, an ALD process, a sputtering process, an electrochemical plating (ECP) process, an electroless deposition (ELD) process, or some other suitable process. In some embodiments, a planarization process (e.g., a CMP process or some other suitable process) is performed on the BTSV 168 and dielectric layer 440 to further delimit the BTSV 168 after depositing the layer(s) of the BTSV 168.

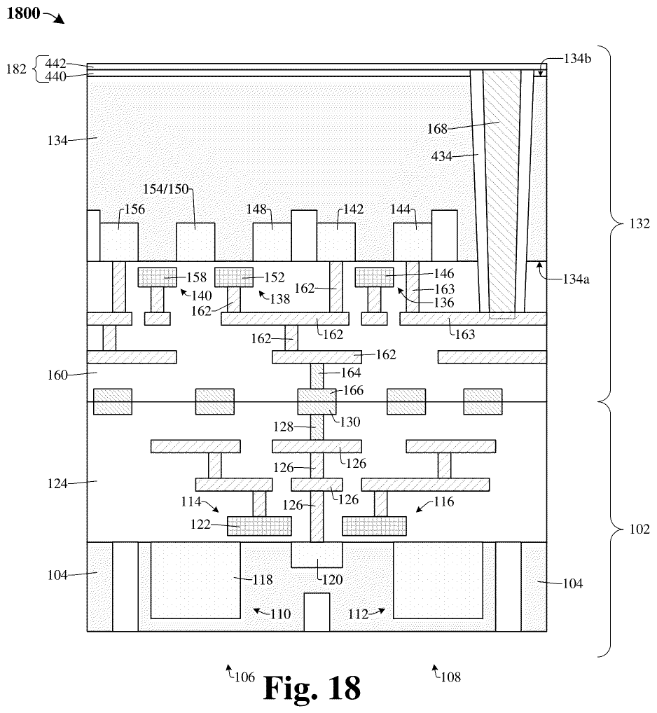

As shown in cross-sectional view 1800 of FIG. 18, a dielectric layer 442 is deposited on dielectric layer 440, dielectric layer 434, and BTSV 168. In some embodiments, dielectric layer 442 comprises silicon oxide, silicon nitride, or some other suitable material and is deposited by a CVD process, a PVD process, an ALD process, or some other suitable process.

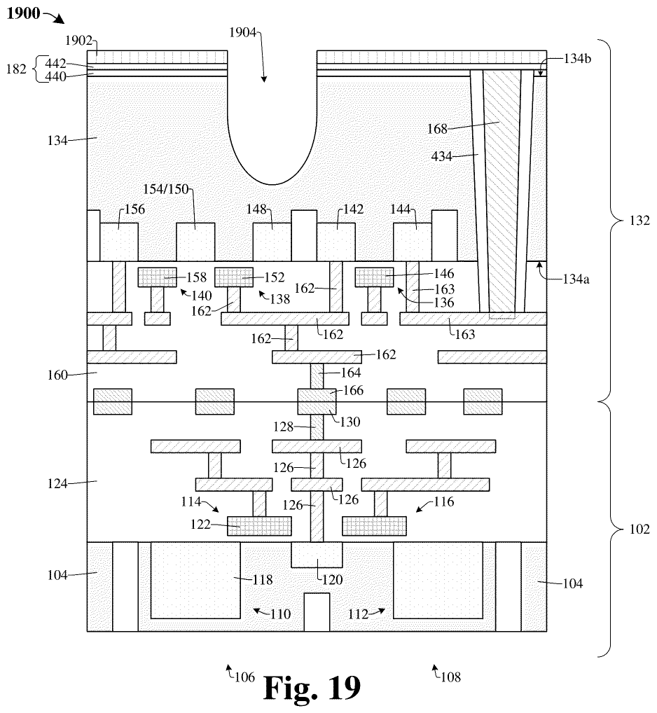

As shown in cross-sectional view 1900 of FIG. 19, dielectric layer 442, dielectric layer 440, and semiconductor substrate 134 are etched to form a capacitor trench 1904 in the backside 134b of semiconductor substrate 134. The etching extends into semiconductor substrate 134 over the pixel transistors 136, 138, 140 from the backside 134b of semiconductor substrate 134. The capacitor trench 1904 is delimited by sidewalls of dielectric layer 442, sidewalls of dielectric layer 440, sidewalls of semiconductor substrate 134, and a lower surface of semiconductor substrate 134. In some embodiments, a masking layer 1902 is formed over dielectric layer 442 and the etching is performed according to the masking layer 1902. In some embodiments, the etching comprises a dry etching process, a wet etching process, or some other suitable process.

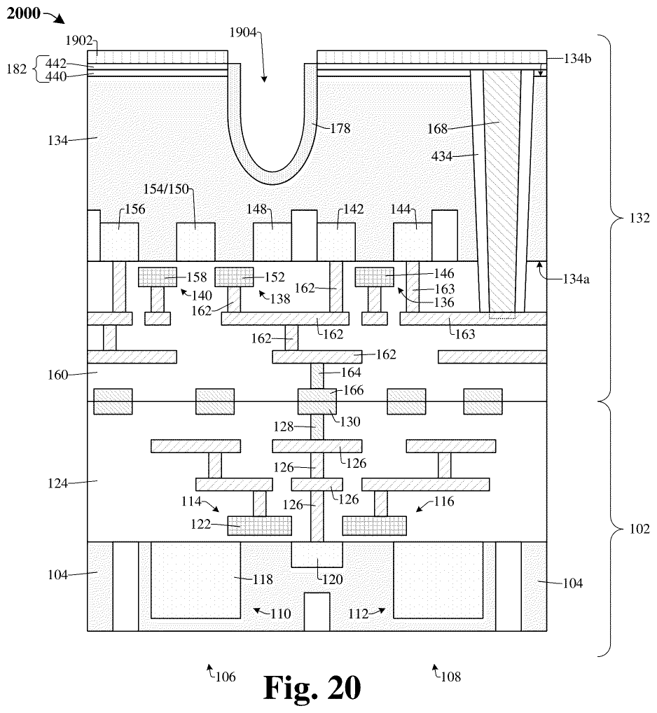

As shown in cross-sectional view 2000 of FIG. 20, a dielectric layer 178 is deposited in the capacitor trench 1904 (e.g., on sidewalls of dielectric layer 442, sidewalls of dielectric layer 440, sidewalls of semiconductor substrate 134, and the lower surface of semiconductor substrate 134). Dielectric layer 178 lines the capacitor trench 1904 and fills portion of the capacitor trench 1904. In some embodiments, dielectric layer 178 comprises silicon oxide, silicon nitride, or some other suitable material and is deposited by a CVD process, a PVD process, an ALD process, or some other suitable process. In some embodiments, dielectric layer 178 is deposited with masking layer 1902 in place over dielectric layer 442.

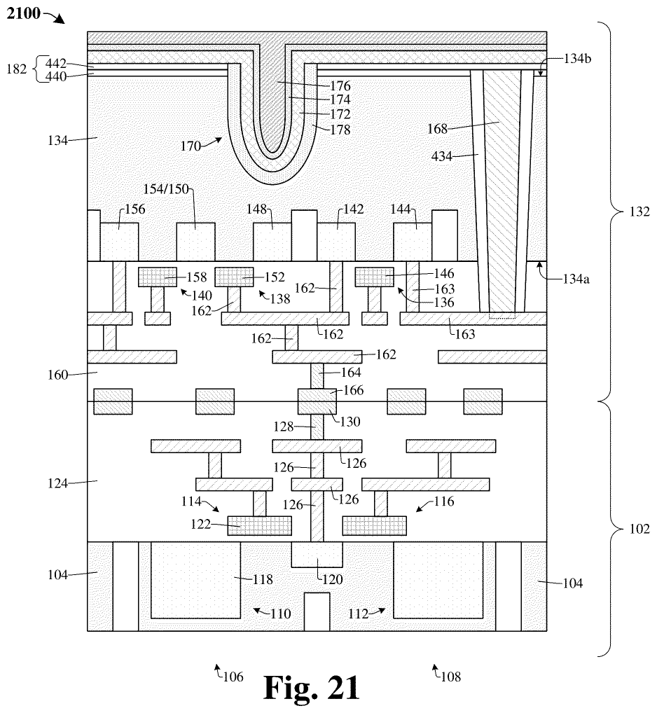

As shown in cross-sectional view 2100 of FIG. 21, a lateral overflow integration capacitor (LOFIC) 170 is formed along the backside 134b of semiconductor substrate 134 and in the capacitor trench 1904. A first electrode layer 172 of the LOFIC 170 is deposited in the capacitor trench 1904, on dielectric layer 178, and on dielectric layer 442. An insulator layer 174 of the LOFIC 170 is deposited in the capacitor trench 1904 and on the first electrode layer 172. A second electrode layer 176 of the LOFIC 170 is deposited in the capacitor trench 1904 and on the insulator layer 174. The second electrode layer 176 fills the capacitor trench 1904. In some embodiments, the first electrode layer 172 and/or the second electrode layer 176 comprise titanium nitride or some other suitable material and are deposited by CVD processes, PVD processes, ALD processes, sputtering processes, ECP processes, ELD processes, or some other suitable processes. In some embodiments, the insulator layer 174 comprises a high-k dielectric (e.g., aluminum oxide, hafnium oxide, zirconium oxide, or the like) or some other suitable material and is deposited by a CVD processes, a PVD processes, an ALD processes, or some other suitable process.

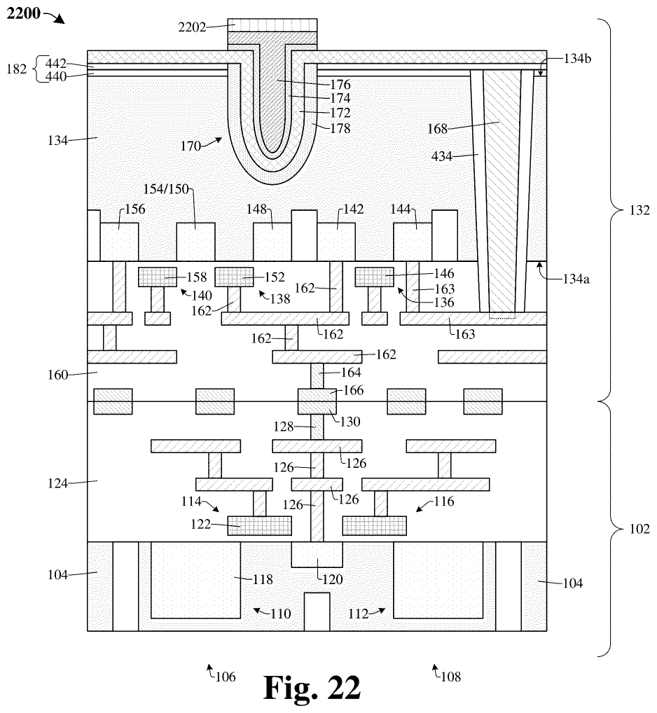

As shown in cross-sectional view 2200 of FIG. 22, the second electrode layer 176 and the insulator layer 174 are etched to further delimit the second electrode layer 176 and the insulator layer 174. In some embodiments, a masking layer 2202 is formed over the second electrode layer 176 and the etching is performed according to the masking layer 2202. In some embodiments, the etching comprises a dry etching process or some other suitable process.

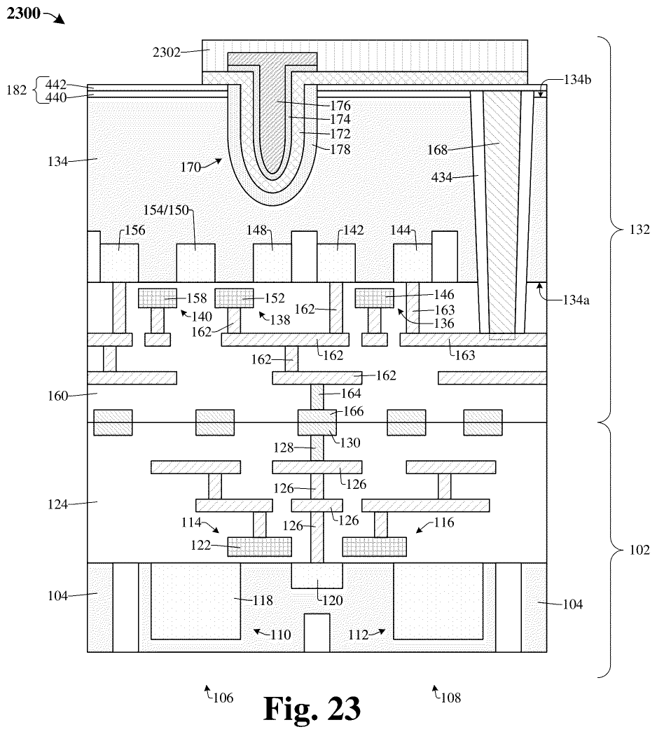

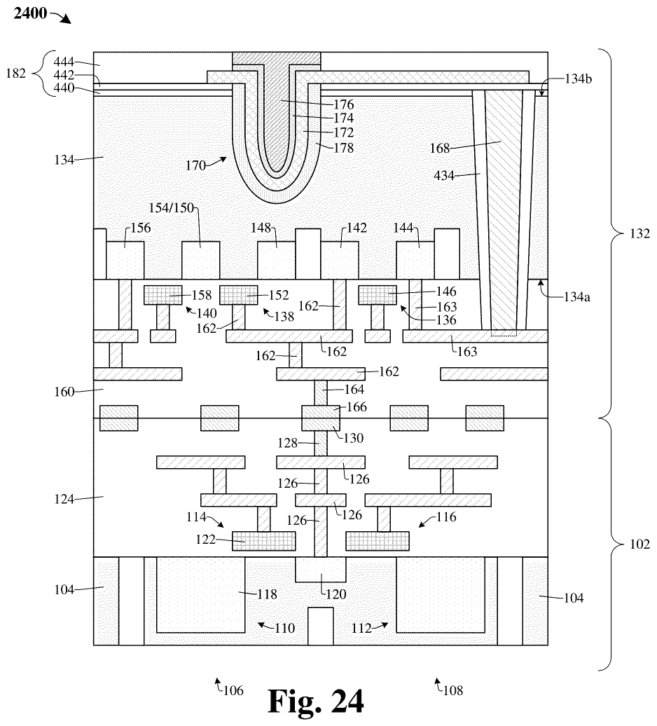

FIGS. 23-26 illustrate cross-sectional views 2300-2600 of some embodiments of a method for coupling the first electrode layer 172 to the BTSV 168.

As shown in cross-sectional view 2300 of FIG. 23, the first electrode layer 172 is etched to further delimit the first electrode layer 172. The first electrode layer 172 remains directly over the BTSV 168 after the etching. In some embodiments, a masking layer 2302 is formed over the second electrode layer 176 and the first electrode layer 172, and the etching is performed according to the masking layer 2302. In some embodiments, the etching comprises a dry etching process or some other suitable process.

As shown in cross-sectional view 2400 of FIG. 24, a dielectric layer 444 is deposited over the first electrode layer 172 and the second electrode layer 176. Further, a planarization process is performed on dielectric layer 444 and the second electrode layer 176. In some embodiments, dielectric layer 444 comprises silicon oxide, silicon nitride, or some other suitable material and is deposited by a CVD process, a PVD process, an ALD process, or some other suitable process. In some embodiments, the planarization process is or comprises a CMP or some other suitable process.

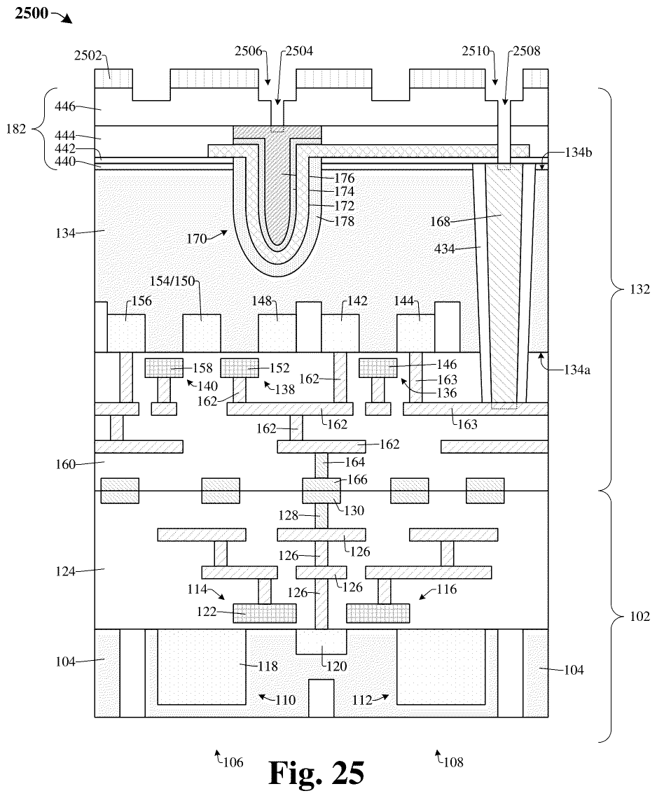

As shown in cross-sectional view 2500 of FIG. 25, dielectric layer 446 is deposited over dielectric layer 444 and the second electrode layer 176. Further, dielectric layer 446 is etched to form openings 2504, 2506 therein. Furthermore, dielectric layer 446, dielectric layer 444, the first electrode layer 172, and dielectric layer 442 are etched to form openings 2508, 2510 therein. Openings 2504, 2506 uncover a portion of the second electrode layer 176. Openings 2508, 2510 uncover a portion of the lower surface of the BTSV and a portion of the first electrode layer 172 (e.g., sidewalls of the first electrode layer 172). Opening 2508 is delimited by sidewalls of dielectric layer 446, sidewalls of dielectric layer 444, sidewalls of the first electrode layer 172, sidewalls of dielectric layer 442, and the lower surface of the BTSV 168.

In some embodiments, dielectric layer 446 comprises silicon oxide, silicon nitride, or some other suitable material and is deposited by a CVD process, a PVD process, an ALD process, or some other suitable process. In some embodiments, one or more masking layers (e.g., masking layer 2502) are formed over dielectric layer 446 and the etching is performed according to the masking layer(s). In some embodiments, the etching comprises a dry etching process or some other suitable process. In some embodiments, openings 2504, 2508 are formed with a first etching process and a first masking layer, and openings 2506, 2510 are formed with a second etching process and a second masking layer. In some embodiments, the etching extends slightly into the second electrode layer 176 and/or slightly into the BTSV 168.

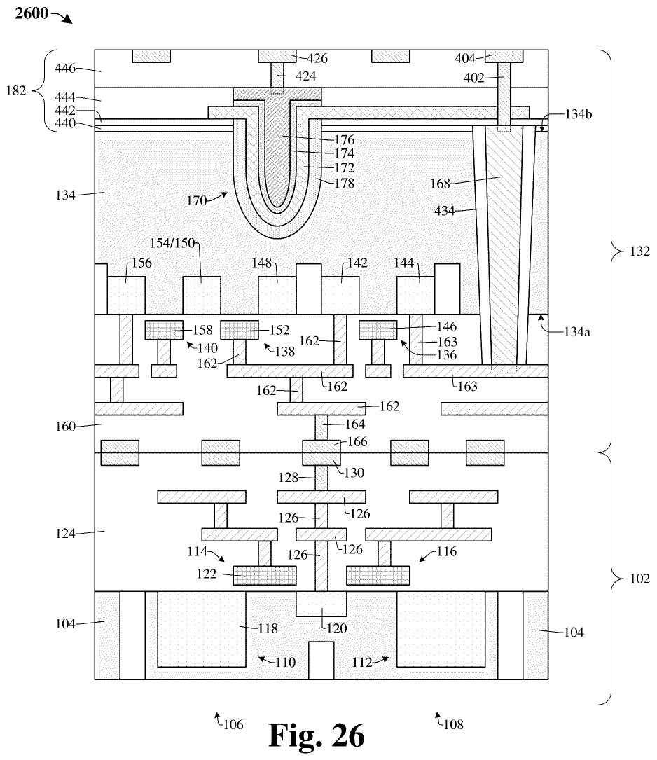

As shown in cross-sectional view 2600 of FIG. 26, backside conductive bonding contact 424 and backside conductive bonding pad 426 are formed in openings 2504, 2506, respectively. Further, backside conductive bonding contact 402 and backside conductive bonding pad 404 are formed in openings 2508, 2510, respectively. In some embodiments, forming the backside conductive boning contacts 402, 424 and the backside conductive bonding pads 404, 426 comprises depositing a conductive barrier layer in the openings 2504, 2506, 2508, 2510 and depositing a conductive fill layer over the conductive barrier layer to fill the openings. In some embodiments, the backside conductive boning contacts 402, 424 and the backside conductive bonding pads 404, 426 comprises copper, tungsten, aluminum, or some other suitable material and is deposited by a CVD process, a PVD process, an ALD process, a sputtering process, an ECP process, an ELD process, or some other suitable process. In some embodiments, a planarization process (e.g., a CMP process or some other suitable process) is performed on the backside conductive bonding pads 404, 426 and dielectric layer 446 after deposition.

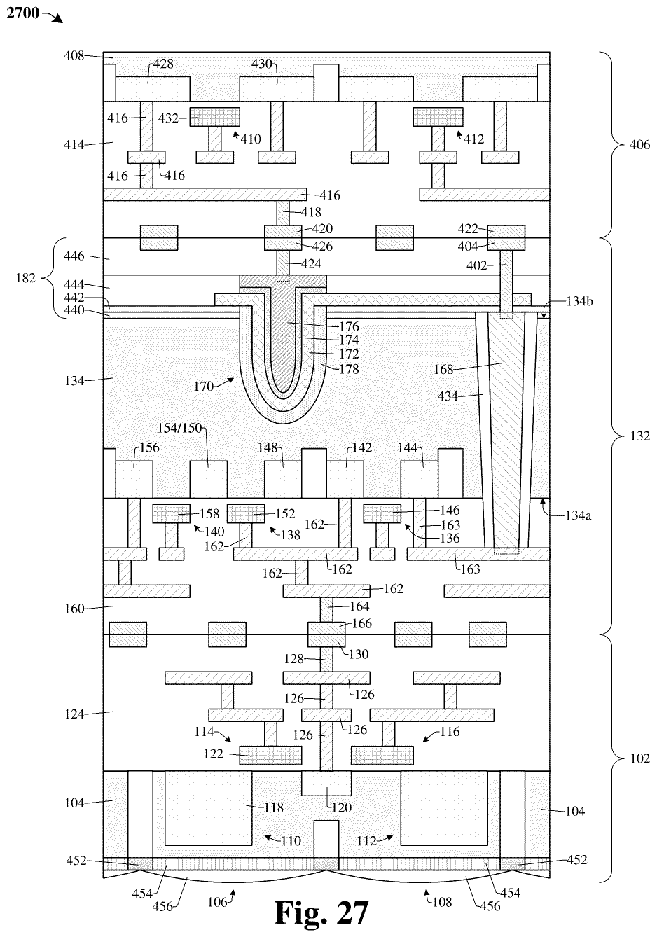

As shown in cross-sectional view 2700 of FIG. 27, transistors 410, 412 are formed along a frontside of a third semiconductor substrate 408 of a third semiconductor chip. Further, a dielectric structure 414 conductive interconnects 416, conductive bonding contact 418, and conductive bonding pads 420, 422 are formed on the frontside of the third semiconductor substrate 408.

Next, the third semiconductor chip 406 and the second semiconductor chip 132 are bonded together. For example, backside conductive bonding pad 404 and conductive bonding pad 422 are bonded together at an interface between the second semiconductor chip 132 and the third semiconductor chip 406. Further, backside conductive bonding pad 426 and conductive bonding pad 420 are bonded together at the interface between the second semiconductor chip 132 and the third semiconductor chip 406. Furthermore, dielectric structure 182 and a dielectric structure 414 are bonded together at the interface. In some embodiments, the bonding comprises a fusion bonding process, a direct bonding process, or some other suitable process.

In some embodiments, an anti-reflection layer (not shown) is formed along the backside of the first semiconductor substrate 104. In some embodiments, a passivation layer (not shown) is formed over the anti-reflection layer. In some embodiments, grid structure 452 is formed over the DTI structure(s) 450 and the passivation layer. In some embodiments, color filters 454 are formed over the passivation layer. In some embodiments, micro-lenses 456 are formed over the color filters 454.

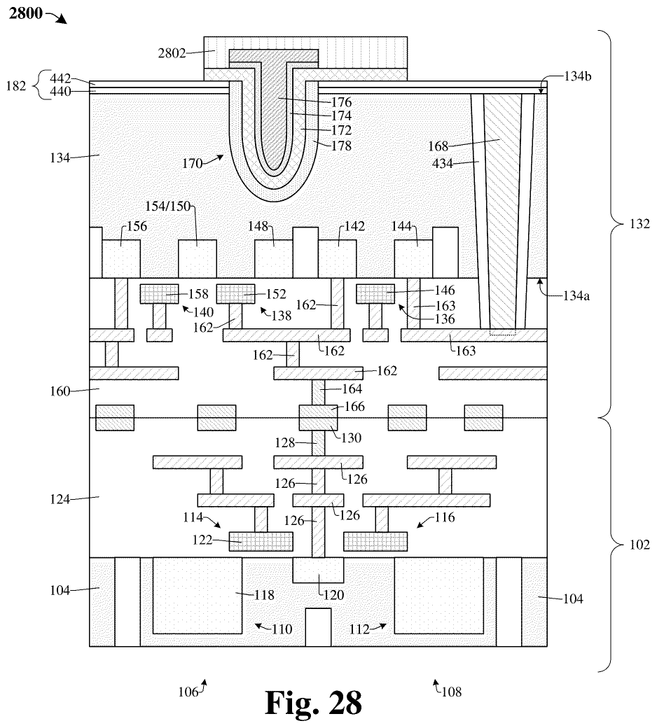

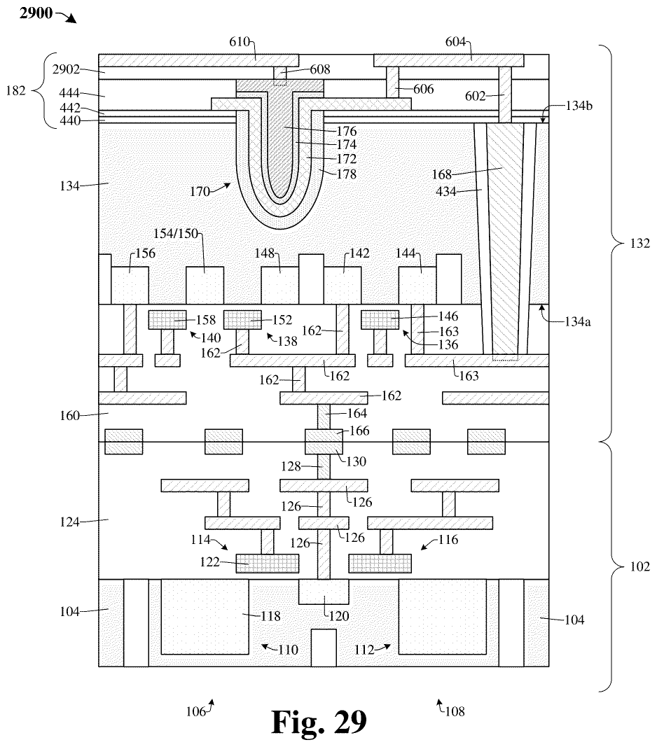

FIGS. 28-32 illustrate cross-sectional views 2800-3200 of some other embodiments of a method for coupling the first electrode layer 172 to the BTSV 168.

As shown in cross-sectional view 2800 of FIG. 28, the first electrode layer 172 is etched to further delimit the first electrode layer 172. The first electrode layer 172 is removed from directly over the BTSV 168 by the etching. In some embodiments, a masking layer 2802 is formed over the second electrode layer 176 and the first electrode layer 172, and the etching is performed according to the masking layer 2802. In some embodiments, the etching comprises a dry etching process or some other suitable process.

As shown in cross-sectional view 2900 of FIG. 29, a dielectric layer 444 is deposited over the first electrode layer 172 and the second electrode layer 176. A dielectric layer 2902 is deposited over dielectric layer 444. In some embodiments, dielectric layer 2902 comprises silicon oxide, silicon nitride, or some other suitable material and is deposited by a CVD process, a PVD process, an ALD process, or some other suitable process.

A backside conductive via 602 is formed on the BTSV 168. A backside conductive via 606 is formed on the first electrode layer 172. A backside conductive via 608 is formed on the second electrode layer 176. A backside conductive line 604 is formed on backside conductive vias 602, 606. A backside conductive line 610 is formed on backside conductive via 608. In some embodiments, backside conductive vias 602, 606, 608 and backside conductive lines 604, 610 comprise copper, aluminum, tungsten, or some other suitable material and are deposited by one or more CVD processes, PVD processes, ALD processes, ECP processes, ELD processes, or some other suitable processes.

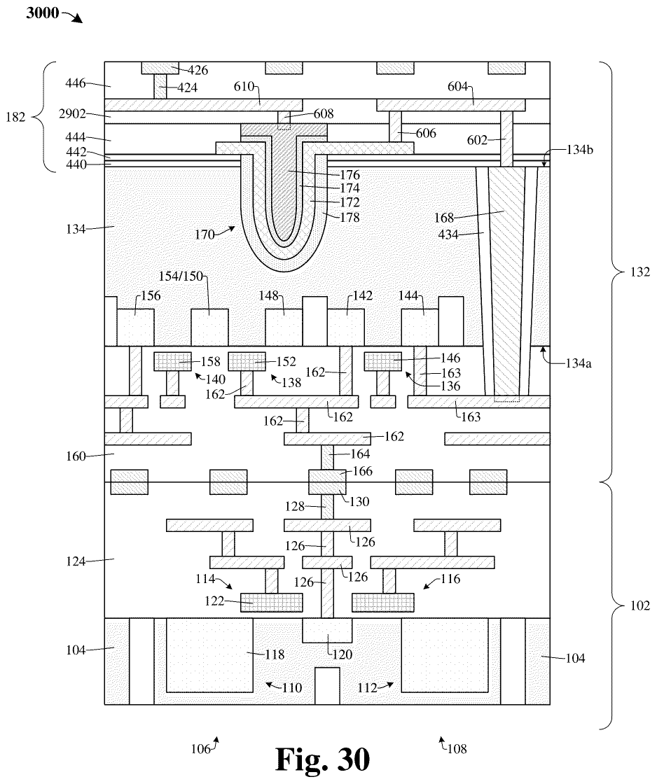

As shown in cross-sectional view 3000 of FIG. 30, dielectric layer 446 is deposited over dielectric layer 2902. Further, backside conductive bonding contact 424 is formed on backside conductive line 610, and backside conductive bonding pad 426 is formed on is formed on the backside conductive bonding contact 424.

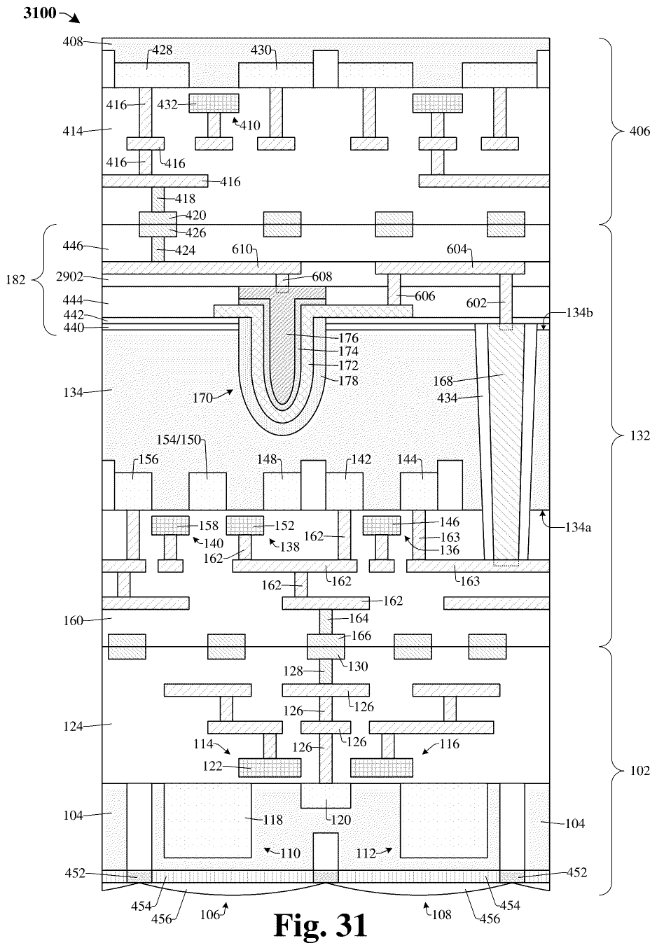

As shown in cross-sectional view 3100 of FIG. 31, the third semiconductor chip 406 and the second semiconductor chip 132 are bonded together.

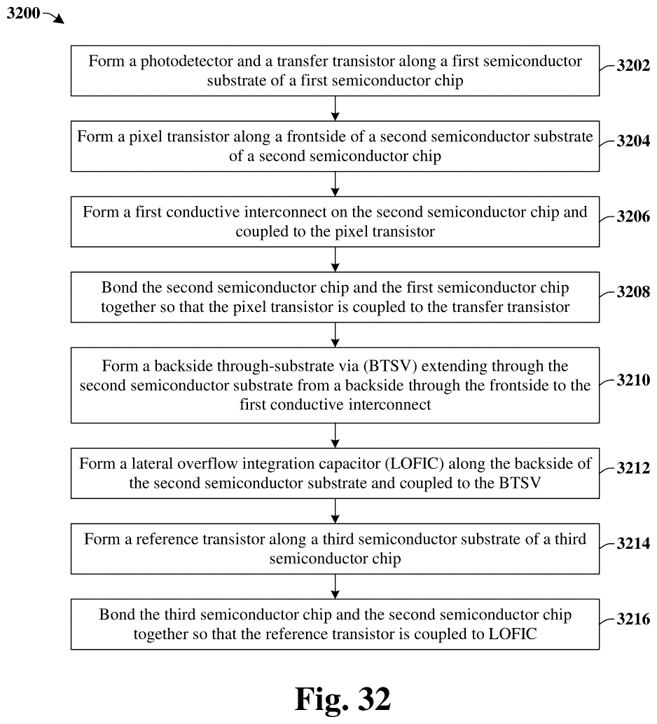

FIG. 32 illustrates a flow diagram of some embodiments of a method 3200 for forming an image sensor integrated chip including a LOFIC along a backside of a semiconductor substrate and coupled to a pixel transistor that is along a frontside of the semiconductor substrate by a BTSV that extends through the semiconductor substrate. While method 3200 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At block 3202, form a photodetector and a transfer transistor along a first semiconductor substrate of a first semiconductor chip. FIG. 9 illustrates a cross-sectional view 900 of some embodiments corresponding to block 3202.

At block 3204, form a pixel transistor along a frontside of a second semiconductor substrate of a second semiconductor chip. FIG. 10 illustrates a cross-sectional view 1000 of some embodiments corresponding to block 3204.

At block 3206, form a first conductive interconnect on the second semiconductor chip and coupled to the pixel transistor. FIG. 10 illustrates a cross-sectional view 1000 of some embodiments corresponding to block 3206.

At block 3208, bond the second semiconductor chip and the first semiconductor chip together so that the pixel transistor is coupled to the transfer transistor. FIG. 11 illustrates a cross-sectional view 1100 of some embodiments corresponding to block 3208.

At block 3210, form a backside through-substrate via (BTSV) extending through the second semiconductor substrate from a backside through the frontside to the first conductive interconnect. FIGS. 14-17 illustrate cross-sectional views 1400-1700 of some embodiments corresponding to block 3210.

At block 3212, form a lateral overflow integration capacitor (LOFIC) along the backside of the second semiconductor substrate and coupled to the BTSV. FIGS. 19-26 illustrate cross-sectional views 1900-2600 of some embodiments corresponding to block 3212. FIGS. 19-22 and FIGS. 28-30 illustrate cross-sectional views 1900-2600 and cross-sectional views 2800-3000 of some other embodiments corresponding to block 3212.

At block 3214, form a reference transistor along a third semiconductor substrate of a third semiconductor chip. FIG. 27 illustrates a cross-sectional view 2700 of some embodiments corresponding to block 3214. FIG. 31 illustrates a cross-sectional view 3100 of some other embodiments corresponding to block 3214.

At block 3216, bond the third semiconductor chip and the second semiconductor chip together so that the reference transistor is coupled to LOFIC. FIG. 27 illustrates a cross-sectional view 2700 of some embodiments corresponding to block 3216. FIG. 31 illustrates a cross-sectional view 3100 of some other embodiments corresponding to block 3216.

Thus, the present disclosure relates to an image sensor integrated chip including a lateral overflow integration capacitor (LOFIC) along a backside of a semiconductor substrate and coupled to a pixel transistor that is along a frontside of the semiconductor substrate by a BTSV that extends through the semiconductor substrate.

Accordingly, in some embodiments, the present disclosure relates to an integrated chip including a first transistor along a frontside of a first semiconductor substrate. The first transistor includes a first source/drain, a second source/drain, and a gate. A first conductive interconnect is on the frontside of the first semiconductor substrate and coupled to the second source/drain of the first transistor. A backside through-substrate via (BTSV) extends through the first semiconductor substrate from a backside of the first semiconductor substrate through the frontside of the first semiconductor substrate to the first conductive interconnect. A capacitor is along the backside of the first semiconductor substrate and extends into the first semiconductor substrate from the backside of the first semiconductor substrate. The capacitor includes a first electrode layer, a second electrode layer, and an insulator layer between the first electrode layer and the second electrode layer. The first electrode layer is coupled to the second source/drain of the first transistor by the BTSV and the first conductive interconnect.

In other embodiments, the present disclosure relates to an integrated chip including a photodetector in a first semiconductor substrate of a first semiconductor chip. A transfer transistor is along the first semiconductor substrate. The transfer transistor includes a first source/drain coupled to the photodetector. A first pixel transistor is along a frontside of a second semiconductor substrate of a second semiconductor chip that is bonded to the first semiconductor chip. The first pixel transistor includes a first source/drain coupled to a second source/drain of the transfer transistor by a first conductive bonding pad and a second conductive bonding pad that are bonded together at an interface between the first semiconductor chip and the second semiconductor chip. A backside through-substrate via (BTSV) extends through the second semiconductor substrate from a backside of the second semiconductor substrate through the frontside of the second semiconductor substrate. The BTSV is coupled to a second source/drain of the first pixel transistor by a first conductive interconnect that is on the second semiconductor chip. A lateral overflow integration capacitor (LOFIC) is along the backside of the second semiconductor substrate. The LOFIC includes a first electrode layer coupled to the BTSV and extending along the backside of the second semiconductor substrate and between sidewalls of the second semiconductor substrate. The LOFIC includes a second electrode layer extending along the backside of the second semiconductor substrate, between the sidewalls of the second semiconductor substrate, and between sidewalls of the first electrode layer. The LOFIC includes an insulator layer between the first electrode layer and the second electrode layer.

In yet other embodiments, the present disclosure relates to a method for forming an integrated chip. The method includes forming a first transistor along a frontside of a first semiconductor substrate of a first semiconductor chip. The first transistor includes a first source/drain, a second source/drain, and a gate. The method includes forming a first conductive interconnect on the frontside of the first semiconductor substrate and coupled to the second source/drain of the first transistor. The method includes etching the first semiconductor substrate from a backside toward the frontside to form a through-substrate via opening that extends from the backside through the frontside of the first semiconductor substrate and that uncovers a portion of the first conductive interconnect. The method includes depositing a conductive layer in the through-substrate via opening and on the portion of the first conductive interconnect from the backside of the first semiconductor substrate to form a backside through-substrate via (BTSV). The method includes etching the first semiconductor substrate from the backside toward the frontside to form a capacitor trench in the first semiconductor substrate. The method includes depositing a first electrode layer, an insulator layer, and a second electrode layer in the capacitor trench and along the backside of the first semiconductor substrate to form a capacitor in the capacitor trench and along the backside of the first semiconductor substrate. The first electrode layer is coupled to the second source/drain of the first transistor by the BTSV and the first conductive interconnect.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated chip comprising:
a first transistor along a frontside of a first semiconductor substrate, the first transistor including a first source/drain, a second source/drain, and a gate;
a first conductive interconnect on the frontside of the first semiconductor substrate and coupled to the second source/drain of the first transistor;
a backside through-substrate via (BTSV) extending through the first semiconductor substrate from a backside of the first semiconductor substrate through the frontside of the first semiconductor substrate to the first conductive interconnect; and
a capacitor along the backside of the first semiconductor substrate and extending into the first semiconductor substrate from the backside of the first semiconductor substrate, the capacitor including a first electrode layer, a second electrode layer, and an insulator layer between the first electrode layer and the second electrode layer, wherein the first electrode layer is coupled to the second source/drain of the first transistor by the BTSV and the first conductive interconnect.

2. The integrated chip of claim 1, further comprising:
a photodetector in a second semiconductor substrate and a transfer transistor along the second semiconductor substrate, the transfer transistor including a first source/drain coupled to the photodetector, the transfer transistor including a second source/drain coupled to the first source/drain of the first transistor; and
a second transistor along the frontside of the first semiconductor substrate, the second transistor including a gate coupled to the first source/drain of the first transistor and the second source/drain of the transfer transistor.

3. The integrated chip of claim 1, further comprising:
a first backside conductive bonding contact and a first backside conductive bonding pad on the backside of the first semiconductor substrate, the first backside conductive bonding contact extending from the first backside conductive bonding pad through the first electrode layer to the BTSV and coupling the first electrode layer to the BTSV.

4. The integrated chip of claim 3, wherein the first backside conductive bonding contact directly contacts a sidewall of the first electrode layer and a lower surface of the BTSV.

5. The integrated chip of claim 3, further comprising:
a second backside conductive bonding contact and a second backside conductive bonding pad on the backside of the first semiconductor substrate, the second backside conductive bonding contact extending from the second backside conductive bonding pad to the second electrode layer and coupling the second backside conductive bonding pad to the second electrode layer.

6. The integrated chip of claim 3, further comprising:
a second conductive bonding pad bonded and coupled to the first backside conductive bonding pad, wherein the first backside conductive bonding pad is directly between the first backside conductive bonding contact and the second conductive bonding pad.

7. The integrated chip of claim 1, further comprising:
a first backside conductive via, a second backside conductive via, and a first backside conductive line on the backside of the first semiconductor substrate, the first backside conductive via extending from the first backside conductive line to the BTSV and coupling the first backside conductive line to the BTSV, the second backside conductive via extending from the first backside conductive line to the first electrode layer and coupling the first backside conductive line to the first electrode layer.

8. The integrated chip of claim 7, further comprising:
a third backside conductive via and a second backside conductive line on the backside of the first semiconductor substrate, the third backside conductive via extending from the second backside conductive line to the second electrode layer and coupling the second backside conductive line to the second electrode layer.

9. The integrated chip of claim 8, further comprising:
a first backside conductive bonding contact and a first backside conductive bonding pad on the backside of the first semiconductor substrate, the first backside conductive bonding contact extending from the first backside conductive bonding pad to the second backside conductive line and coupling the first backside conductive bonding pad to the second backside conductive line; and
a second conductive bonding pad bonded and coupled to the first backside conductive bonding pad.

10. The integrated chip of claim 1, further comprising:
a backside conductive via and a backside conductive line on the backside of the first semiconductor substrate, the backside conductive via extending from the backside conductive line through the first electrode layer to the BTSV and coupling the first electrode layer to the BTSV.

11. The integrated chip of claim 1, wherein the first electrode layer directly contacts the BTSV.

12. An integrated chip comprising:
a photodetector in a first semiconductor substrate of a first semiconductor chip;
a transfer transistor along the first semiconductor substrate, the transfer transistor including a first source/drain coupled to the photodetector;
a first pixel transistor along a frontside of a second semiconductor substrate of a second semiconductor chip that is bonded to the first semiconductor chip, the first pixel transistor including a first source/drain coupled to a second source/drain of the transfer transistor by a first conductive bonding pad and a second conductive bonding pad that are bonded together at an interface between the first semiconductor chip and the second semiconductor chip;
a backside through-substrate via (BTSV) extending through the second semiconductor substrate from a backside of the second semiconductor substrate through the frontside of the second semiconductor substrate, wherein the BTSV is coupled to a second source/drain of the first pixel transistor by a first conductive interconnect that is on the second semiconductor chip; and
a lateral overflow integration capacitor (LOFIC) along the backside of the second semiconductor substrate, the LOFIC comprising a first electrode layer coupled to the BTSV and extending along the backside of the second semiconductor substrate and between sidewalls of the second semiconductor substrate, a second electrode layer extending along the backside of the second semiconductor substrate, between the sidewalls of the second semiconductor substrate, and between sidewalls of the first electrode layer, and an insulator layer between the first electrode layer and the second electrode layer.

13. The integrated chip of claim 12, further comprising:
a reference transistor along a third semiconductor substrate of a third semiconductor chip that is bonded to the second semiconductor chip, the reference transistor including a first source/drain coupled to the second electrode layer by a third conductive bonding pad and a fourth conductive bonding pad that are bonded together at an interface between the second semiconductor chip and the third semiconductor chip, the reference transistor including a second source/drain coupled to a reference voltage terminal.

14. The integrated chip of claim 13, further comprising:
a first conductive bonding contact and a fifth conductive bonding pad on the second semiconductor chip, the first conductive bonding contact extending from the fifth conductive bonding pad through the first electrode layer to the BTSV and coupling the first electrode layer to the BTSV;
a sixth conductive bonding pad on the third semiconductor chip, wherein the sixth conductive bonding pad is bonded and coupled to the fifth conductive bonding pad; and
a second conductive bonding contact on the second semiconductor chip, the second conductive bonding contact extending from the third conductive bonding pad to the second electrode layer and coupling the third conductive bonding pad to the second electrode layer.

15. The integrated chip of claim 13, further comprising:
a first backside conductive via, a second backside conductive via, and a first backside conductive line on the second semiconductor chip, the first backside conductive via extending from the first backside conductive line to the BTSV and coupling the first backside conductive line to the BTSV, the second backside conductive via extending from the first backside conductive line to the first electrode layer and coupling the first backside conductive line to the first electrode layer;
a third backside conductive via and a second backside conductive line on the second semiconductor chip, the third backside conductive via extending from the second backside conductive line to the second electrode layer and coupling the second backside conductive line to the second electrode layer; and
a backside conductive bonding contact on the second semiconductor chip, the backside conductive bonding contact extending from the third conductive bonding pad to the second backside conductive line and coupling the third conductive bonding pad to the second backside conductive line.

16. The integrated chip of claim 12, further comprising:
a dielectric layer separating the first electrode layer from the sidewalls of the second semiconductor substrate.

17. A method for forming an integrated chip, the method comprising:
forming a first transistor along a frontside of a first semiconductor substrate of a first semiconductor chip, the first transistor including a first source/drain, a second source/drain, and a gate;
forming a first conductive interconnect on the frontside of the first semiconductor substrate and coupled to the second source/drain of the first transistor;
etching the first semiconductor substrate from a backside toward the frontside to form a through-substrate via opening that extends from the backside through the frontside of the first semiconductor substrate and that uncovers a portion of the first conductive interconnect;
depositing a conductive layer in the through-substrate via opening and on the portion of the first conductive interconnect from the backside of the first semiconductor substrate to form a backside through-substrate via (BTSV);
etching the first semiconductor substrate from the backside toward the frontside to form a capacitor trench in the first semiconductor substrate; and
depositing a first electrode layer, an insulator layer, and a second electrode layer in the capacitor trench and along the backside of the first semiconductor substrate to form a capacitor in the capacitor trench and along the backside of the first semiconductor substrate, wherein the first electrode layer is coupled to the second source/drain of the first transistor by the BTSV and the first conductive interconnect.

18. The method of claim 17, further comprising:
forming a photodetector in a second semiconductor substrate and a transfer transistor along the second semiconductor substrate of a second semiconductor chip, the transfer transistor including a first source/drain coupled to the photodetector;
bonding the second semiconductor chip and the first semiconductor chip together such that a second source/drain of the transfer transistor is coupled to the first source/drain of the first transistor;
forming a second transistor along a third semiconductor substrate of a third semiconductor chip, the second transistor including a first source/drain coupled to a reference voltage terminal; and
bonding the third semiconductor chip and the first semiconductor chip together such that a second source/drain of the second transistor is coupled to the second electrode layer.

19. The method of claim 18, further comprising:
forming a first conductive bonding contact and a first conductive bonding pad on the first semiconductor chip, the first conductive bonding contact extending from the first conductive bonding pad through the first electrode layer to the BTSV and coupling the first electrode layer to the BTSV;
forming a second conductive bonding contact and a second conductive bonding pad on the first semiconductor chip, the second conductive bonding contact extending from the second conductive bonding pad to the second electrode layer and coupling the second conductive bonding pad to the second electrode layer; and
forming a third conductive bonding pad and a fourth conductive bonding pad on the third semiconductor chip, wherein the bonding the third semiconductor chip and the first semiconductor chip together includes bonding the third conductive bonding pad to the first conductive bonding pad and bonding the fourth conductive bonding pad to the second conductive bonding pad.

20. The method of claim 18, further comprising:
forming a first backside conductive via, a second backside conductive via, and a first backside conductive line on the first semiconductor chip, the first backside conductive via extending from the first backside conductive line to the BTSV and coupling the first backside conductive line to the BTSV, the second backside conductive via extending from the first backside conductive line to the first electrode layer and coupling the first backside conductive line to the first electrode layer;
forming a third backside conductive via and a second backside conductive line on the first semiconductor chip, the third backside conductive via extending from the second backside conductive line to the second electrode layer and coupling the second backside conductive line to the second electrode layer;
forming a first conductive bonding contact and a first conductive bonding pad on the first semiconductor chip, the first conductive bonding contact extending from the first conductive bonding pad to the second backside conductive line and coupling the first conductive bonding pad to the second backside conductive line; and
forming a second conductive bonding pad on the third semiconductor chip and coupled to the second source/drain of the second transistor, wherein the bonding the third semiconductor chip and the first semiconductor chip together includes bonding the second conductive bonding pad to the first conductive bonding pad.
